(19) United States
(12) Patent Application Publication
(10) Pub. No.: US 2015/0344636 A1
(43) Pub. Date: Dec. 3, 2015

(54) Curable Silicone Composition, Cured Product Thereof, And Optical Semiconductor Device

(71) Applicant: DOW CORNING TORAY CO., LTD., Chiyodo-ku, Tokyo (JP)

(72) Inventors: Tomohiro Iimura, Ichihara-shi (JP); Kazuhiro Nishijima, Ichihara-shi (JP); Michitaka Suto, Ichihara-shi (JP); Haruhiko Furukawa, Ichihara-shi (JP); Yoshitsugu Morita, Ichihara-shi (JP)

(21) Appl. No.: 14/655,536

(22) PCT Filed: Dec. 24, 2013
(86) PCT No.: PCT/JP2013/085315

§ 371 Date: Jun. 25, 2015

(30) Foreign Application Priority Data
Dec. 28, 2012 (JP) 2012-288120

(51) Int. Cl. C08G 77/00; H01L 31/0203; H01L 27/146; H01L 33/56

(52) U.S. Cl. CPC C08G 77/80; H01L 33/56; H01L 31/0203; H01L 27/14618; C08G 2190/00

(57) ABSTRACT

The present invention relates to a curable silicone composition comprising: (A) an organopolysiloxane resin having at least two alkenyl groups in a molecule; (B) a straight-chain organopolysiloxane having at least two alkenyl groups and not having silicon-bonded hydrogen atoms in a molecule; (C) an organopolysiloxane having a condensed polycyclic aromatic group or a group including a condensed polycyclic aromatic group; and (D) a hydrosilylation reaction catalyst. The curable silicone composition has excellent handling and processability and can form a cured product with a high refractive index and low gas permeability.

### TECHNICAL FIELD

The present invention relates to a curable silicone composition, a cured product formed by curing the composition, and an optical semiconductor device produced using the composition.

Priority is claimed on Japanese Patent Application No. 2012-288120, filed on Dec. 28, 2012, the content of which is incorporated herein by reference.

### BACKGROUND ART

Curable silicone compositions are used as sealing materials or protective coating materials for optical semiconductor elements in optical semiconductor devices such as light emitting diodes (LEDs). However, since the gas permeability of a cured product of a curable silicone composition is high, problems such as the discoloration of the sealing material due to corrosive gas and a reduction of brightness due to the corrosion of silver plate on the LED substrate occur in a high-brightness LED with high optical intensity and a large amount of heat generation.

Therefore, a curable silicone composition which forms a cured product with low gas permeability is proposed in Japanese Unexamined Patent Application Publication No. 2012-052045A, but such a curable silicone composition is problematic in that the viscosity is high, the handling and processability is poor, and the gas permeability of the cured product thereof is not sufficiently low.

An object of the present invention is to provide a curable silicone composition having excellent handling and processability and forming a cured product with a high refractive index and low gas permeability. In addition, another object of the present invention is to provide a cured product having a high refractive index and a low gas permeability and to provide an optical semiconductor device having excellent reliability.

### DISCLOSURE OF INVENTION

The curable silicone composition of the present invention comprises:
(A) an organopolysiloxane resin having at least two alkenyl groups in a molecule and represented by the average unit formula:

(R¹R²₂SiO_{1/2})ₐ(R³₂SiO_{2/2})_{b}(R⁴SiO_{3/2})_{c}
wherein R¹ is an alkenyl group having from 2 to 12 carbons; R² are the same or different, and are each an alkyl group having from 1 to 12 carbons, an alkenyl group having from 2 to 12 carbons, an aryl group having from 6 to 20 carbons, or an aralkyl group having from 7 to 20 carbons; R³ are the same or different, and are each an alkyl group having from 1 to 12 carbons, an alkenyl group having from 2 to 12 carbons, or a phenyl group; R⁴ is an aryl group having from 6 to 20 carbons, or an aralkyl group having from 7 to 20 carbons; and a, b, and c are numbers that satisfy such that 0.01≦a≦0.5, 0≦b≦0.7, 0.1≦c<0.9, and a+b+c=1;
(B) a straight-chain organopolysiloxane having at least two alkenyl groups and not having silicon-bonded hydrogen atoms in a molecule, in an amount of 0 to 70 mass % of the composition;
(C) an organopolysiloxane represented by the general formula:

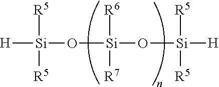

wherein R⁵ are the same or different, and are each an alkyl group having from 1 to 12 carbons, an aryl group having from 6 to 20 carbons, or an aralkyl group having from 7 to 20 carbons; R⁶ is a condensed polycyclic aromatic group or a group containing a condensed polycyclic aromatic group; R⁷ is an alkyl group having from 1 to 12 carbons or a phenyl group; and n is an integer from 1 to 100, in an amount such that the number of silicon-bonded hydrogen atoms in the present component is from 0.1 to 5 moles per 1 mol of total alkenyl groups in components (A) and (B); and
(D) an effective amount of a hydrosilylation reaction catalyst.

The cured product of the present invention is formed by curing the aforementioned curable silicone composition.

The optical semiconductor device of the present invention is produced by sealing an optical semiconductor element with a cured product of the curable silicone composition described above.

### EFFECTS OF INVENTION

The curable silicone composition of the present invention has excellent handling and processability and forms a cured product with a high refractive index and low gas permeability. Furthermore, the cured product of the present invention is characterized by having a high refractive index and a low gas permeability, and the optical semiconductor device of the present invention is characterized by exhibiting excellent reliability.

### BRIEF DESCRIPTION OF THE DRAWINGS

FIG. 1 is a cross-sectional view of an LED that is an example of the optical semiconductor device of the present invention.

### DETAILED DESCRIPTION OF THE INVENTION

First, the curable silicone composition of the present invention will be described in detail.

Component (A) is a base compound of this composition and is an organopolysiloxane resin represented by the average unit formula:

(R¹R²₂SiO_{1/2})ₐ(R³₂SiO_{2/2})_{b}(R⁴SiO_{3/2})_{c}

and having at least two alkenyl groups in a molecule.

In the formula, R¹ is an alkenyl group having from 2 to 12 carbons, examples of which include vinyl groups, allyl groups, butenyl groups, pentenyl groups, hexenyl groups, heptenyl groups, octenyl groups, nonenyl groups, decenyl groups, undecenyl groups, and dodecenyl groups, and a vinyl group is preferable.

In the formula, R² are the same or different, and are each an alkyl group having from 1 to 12 carbons, an alkenyl group having from 2 to 12 carbons, an aryl group having from 6 to 20 carbons, or an aralkyl group having from 7 to 20 carbons. Examples of the alkyl group of R² include methyl groups, ethyl groups, propyl groups, butyl groups, pentyl groups, hexyl groups, heptyl groups, octyl groups, nonyl groups, decyl groups, undecyl groups, and dodecyl groups, and a methyl group is preferable. Examples of the alkenyl group of R² include the same groups described for R¹. Of these, a vinyl group is preferable. Examples of the aryl groups of R² include phenyl groups, tolyl groups, xylyl groups, naphthyl groups, anthracenyl groups, phenanthryl groups, pyrenyl groups, and groups in which the hydrogen atoms of these aryl groups are substituted with alkyl groups such as methyl groups and ethyl groups; alkoxy groups such as methoxy groups and ethoxy groups; or halogen atoms such as chlorine atoms and bromine atoms. Of these, phenyl groups and naphthyl groups are preferable. Examples of the aralkyl groups of R² include benzyl groups, phenethyl groups, naphthyl ethyl groups, naphthyl propyl groups, anthracenyl ethyl groups, phenanthryl ethyl groups, pyrenyl ethyl groups, and groups in which the hydrogen atoms of these aralkyl groups are substituted with alkyl groups such as methyl groups and ethyl groups; alkoxy groups such as methoxy groups and ethoxy groups; or halogen atoms such as chlorine atoms and bromine atoms.

In the formula, R³ are the same or different, and are alkyl groups having from 1 to 12 carbons, alkenyl groups having from 2 to 12 carbons, or phenyl groups. Examples of the alkyl group of R³ include the same alkyl groups described for the aforementioned R², and the alkyl group is preferably a methyl group. Examples of the alkenyl group of R³ include the same groups described for R¹. Of these, a vinyl group is preferable.

In the formula, R⁴ is an aryl group having from 6 to 20 carbons or an aralkyl group having from 7 to 20 carbons. Examples of the aryl group of R⁴ include the same aryl groups described for the aforementioned R², and the aryl group is preferably a phenyl group or naphthyl group. Examples of the aralkyl group of R⁴ include the same aralkyl groups described for the aforementioned R².

In the formula, a, b, and c are respectively numbers satisfying: 0.01≦a≦0.5, 0≦b≦0.7, 0.1≦c≦0.9, and a+b+c=1, preferably numbers satisfying: 0.05≦a≦0.45, 0≦b≦0.5, 0.4≦c<0.85, and a+b+c=1, and even more preferably numbers satisfying: 0.05≦a≦0.4, 0≦b≦0.4, 0.45≦c<0.8, and a+b+c=1. This is because the gas permeability of the cured product is reduced if a is not less than the lower limit of the above-mentioned range and stickiness hardly occurs in the cured product if a is not more than the upper limit of the above-mentioned range. This is also because the hardness of the cured product is favorable and the reliability improves when b is less than or equal to the upper limit of the range described above. This is also because the refractive index of the cured product is favorable when c is greater than or equal to the lower limit of the range described above, and the mechanical characteristics of the cured product improve when c is less than or equal to the upper limit of the range described above.

Component (A) is expressed by the average unit formula described above but may also have siloxane units represented by the formula: R⁸₃SiO_{1/2}, siloxane units represented by the formula: R⁹SiO_{3/2}, or siloxane units represented by the formula: SiO_{4/2} within a range that does not diminish the object of the present invention. In the formula, R⁸ are the same or different, and are each an alkyl group having from 1 to 12 carbons, an aryl group having from 6 to 20 carbons, or an aralkyl group having from 7 to 20 carbons. Examples of the alkyl group of R⁸ include the same alkyl groups described for R². Examples of the aryl group of R⁸ include the same aryl groups described for the aforementioned R². Examples of the aralkyl group of R⁸ include the same aralkyl groups described for the aforementioned R². In the formula, R⁹ is an alkyl group having from 1 to 12 carbons or an alkenyl group having from 2 to 12 carbons. Examples of the alkyl group of R⁹ include the same alkyl groups described for R². Examples of the alkenyl group of R⁹ include the same groups described for R¹. Furthermore, the organopolysiloxane for component (A) may contain silicon-bonded alkoxy groups, such as methoxy groups, ethoxy groups, or propoxy groups, or silicon-bonded hydroxyl groups as long as the objective of the present invention is not impaired.

Component (B), which is an optional component for imparting the cured product of this composition with softness, extensibility, and flexibility, is a straight-chain organopolysiloxane having at least two alkenyl groups and having no silicon-bonded hydrogen atoms in a molecule. Examples of the alkenyl groups in component (B) include alkenyl groups having from 2 to 12 carbons such as vinyl groups, allyl groups, butenyl groups, pentenyl groups, hexenyl groups, heptenyl groups, octenyl groups, nonenyl groups, decenyl groups, undecenyl groups, and dodecenyl groups. Of these, vinyl groups are preferable. Furthermore, groups bonding to silicon atoms other than alkenyl groups in component (B) include alkyl groups having from 1 to 12 carbons, such as methyl groups, ethyl groups, propyl groups, butyl groups, pentyl groups, hexyl groups, heptyl groups, octyl groups, nonyl groups, decyl groups, undecyl groups, and dodecyl groups; aryl groups having from 6 to 20 carbons, such as phenyl groups, tolyl groups, xylyl groups, naphthyl groups, anthracenyl groups, phenanthryl groups, pyrenyl groups, and groups obtained by substituting hydrogen atoms in these aryl groups with alkyl groups such as methyl groups or ethyl groups, alkoxy groups such as methoxy groups and ethoxy groups and halogen atoms such as chlorine atoms and bromine atoms; aralkyl groups having from 7 to 20 carbons, such as benzyl groups, phenethyl groups, naphthyl ethyl groups, naphthyl propyl groups, anthracenyl ethyl groups, phenanthryl ethyl groups, pyrenyl ethyl groups, and groups obtained by substituting hydrogen atoms in these aralkyl groups with alkyl groups such as methyl groups or ethyl groups, alkoxy groups such as methoxy groups and ethoxy groups and halogen atoms such as chlorine atoms and bromine atoms; and halogenated alkyl groups having from 1 to 12 carbons, such as chloromethyl groups and 3,3,3-trifluoropropyl groups, and are preferably methyl groups or phenyl groups.

Examples of such component (B) include copolymers of dimethylsiloxanes and methylvinylsiloxanes capped at both molecular terminals with trimethylsiloxy groups, methylvinylpolysiloxanes capped at both molecular terminals with trimethylsiloxy groups, copolymers of dimethylsiloxanes, methylvinylsiloxanes, and methylphenylsiloxanes capped at both molecular terminals with trimethylsiloxy groups, dimethylpolysiloxanes capped at both molecular terminals with dimethylvinylsiloxy groups, methylvinylpolysiloxanes capped at both molecular terminals with dimethylvinylsiloxy groups, methylphenylpolysiloxanes capped at both molecular terminals with dimethylvinylsiloxy groups, copolymers of dimethylsiloxanes and methylvinylsiloxanes capped at both molecular terminals with dimethylvinylsiloxy groups, copolymers of dimethylsiloxanes, methylvinylsiloxanes, and methylphenylsiloxanes capped at both molecular terminals with dimethylvinylsiloxy groups, methylphenylpolysiloxanes capped at both molecular terminals with methylphenylvinylsiloxy groups, methylphenylpolysiloxanes capped at both molecular terminals with diphenylvinylsiloxy groups, copolymers of methylphenylsiloxanes and diphenylsiloxanes capped at both molecular terminals with methylphenylvinylsiloxy groups, copolymers of methylphenylsiloxanes and diphenylsiloxanes capped at both molecular terminals with diphenylvinylsiloxy groups, and mixtures of two or more types of these organopolysiloxanes.

In this composition, the content of component (B) can be determined as desired but is preferably in a range of from 0 to 70 mass %, more preferably in a range of from 0 to 50 mass %, and particularly preferably in a range of from 0 to 40 mass % of this composition. This is because when the content of component (B) is less than or equal to the upper limit of the aforementioned range, it is possible to impart the cured product with softness, extensibility, and flexibility without increasing the gas permeability of the cured product, which makes it possible to improve the reliability of an optical semiconductor device produced using the composition.

Component (C) is a crosslinking agent of the present composition and is an organopolysiloxane represented by the general formula:

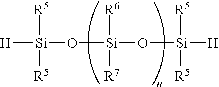

In the formula, R⁵ are the same or different, and are each an alkyl group having from 1 to 12 carbons, an aryl group having from 6 to 20 carbons, or an aralkyl group having from 7 to 20 carbons. Examples of the alkyl group of R⁵ include the same alkyl groups described for the aforementioned R², and the alkyl group is preferably a methyl group. Examples of the aryl group of R⁵ include the same aryl groups described for the aforementioned R², and the aryl group is preferably a phenyl group or naphthyl group. Examples of the aralkyl group of R⁵ include the same aralkyl groups described for the aforementioned R².

In the formula, R⁶ is a condensed polycyclic aromatic group or a group including a condensed polycyclic aromatic group. Examples of the condensed polycyclic aromatic group of R⁶ include naphthyl groups, anthracenyl groups, phenanthryl groups, pyrenyl groups, and such condensed polycyclic aromatic groups where a hydrogen atom is substituted with an alkyl group such as a methyl group, an ethyl group, and the like; with an alkoxy group such as a methoxy group, an ethoxy group, and the like; or with a halogen atom such as a chlorine atom, a bromine atom, and the like. Of these, the naphthyl groups are preferable. Examples of the group including a condensed polycyclic aromatic group of R⁶ include naphthyl ethyl groups, naphthyl propyl groups, anthracenyl ethyl groups, phenanthryl ethyl groups, pyrenyl ethyl groups, and such groups including a condensed polycyclic aromatic group in which a hydrogen atom is substituted with an alkyl group such as a methyl group or an ethyl group; with an alkoxy group such as a methoxy group or an ethoxy group, or with a halogen atom such as a chlorine atom or a bromine atom.

In the formula, R⁷ is an alkyl group having from 1 to 12 carbons or a phenyl group. Examples of the alkyl group of R⁷ include the same alkyl groups described for the aforementioned R². Of these, a methyl group is preferable.

In the formula, n is an integer in a range from 1 to 100, preferably an integer in a range from 1 to 50, and particularly preferably an integer in a range from 1 to 20. This is because when n is less than or equal to the upper limit of the aforementioned range, the handling and processability of the resulting composition improves.

The method of preparing the organopolysiloxane of such component (C) is not particularly limited, but an example is a method of performing a hydrolysis/condensation reaction on a silane compound (I-1) represented by the general formula:

R⁶R⁷SiX₂,

a cyclic siloxane compound (I-2) represented by the general formula:

(R⁶R⁷SiO)ₚ,

or a straight-chain organosiloxane (I-3) represented by the general formula:

HO(R⁶R⁷SiO)ᵣH,

a disiloxane (II-1) represented by the general formula:

HR⁵₂SiOSiR⁵₂H,

and/or a silane compound (II-2) represented by the general formula:

HR⁵₂SiX

in the presence of an acid or an alkali.

In the formulas, R⁵ are the same or different, and are each an alkyl group having from 1 to 12 carbons, an aryl group having from 6 to 20 carbons, or an aralkyl group having from 7 to 20 carbons, examples of which are the same groups as those described above. In the formulas, R⁶ is a condensed polycyclic aromatic group or a group including a condensed polycyclic aromatic group, examples of which are the same groups as those described above. In the formulas, R⁷ is an alkyl group having from 1 to 12 carbons or phenyl group, examples of which are the same groups as those described above. In the formula, p is an integer of 3 or higher, and r is an integer of 2 or higher. In the formulas, X is an alkoxy group such as a methoxy group, an ethoxy group, or a propoxy group; an acyloxy group such as an acetoxy group; a halogen atom such as a chlorine atom or a bromine atom; or a hydroxyl group.

Examples of such a silane compound (I-1) include alkoxysilanes such as naphthylmethyldimethoxysilane, anthracenylmethyldimethoxysilane, phenanthrylmethyldimethoxysilane, pyrenylmethyldimethoxysilane, naphthylethyldimethoxysilane, anthracenylethyldimethoxysilane, phenanthrylethyldimethoxysilane, pyrenylethyldimethoxysilane, naphthylmethyldiethoxysilane, anthracenylmethyldiethoxysilane, phenantrylmethyldiethoxysilane, pyrenylmethyldiethoxysilane, naphthylethyldiethoxysilane, anthracenylethyldiethoxysilane, phenanthrylethyldiethoxysilane, pyrenylethyldiethoxysilane, naphthylphenyldimethoxysilane, anthracenylphenyldimethoxysilane, phenanthrylphenyldimethoxysilane, pyrenylphenyldimethoxysilane, naphthylphenyldiethoxysilane, anthracenylphenyldiethoxysilane, phenanthrylphenyldiethoxysilane, and pyrenylphenyldiethoxysilane; halosilanes such as naphthylmethyldichlorosilane, anthracenylmethyldichlorosilane, phenanthrylmethyldichlorosilane, pyrenylmethyldichlorosilane, naphthylethyldichlorosilane, anthracenylethyldichlorosilane, phenanthrylethyldichlorosilane, pyrenylethyldichlorosilane, naphthylphenyldichlorosilane, anthracenylphenyldichlorosilane, phenanthrylphenyldichlorosilane, and pyrenylphenyldichlorosilane; and hydroxysilanes such as naphthylmethyldihydroxysilane, anthracenylmethyldihydroxysilane, phenanthrylmethyldihydroxysilane, pyrenylmethyldihydroxysilane, naphthylphenyldihydroxysilane, anthracenylphenyldihydroxysilane, phenanthrylphenyldihydroxysilane, and pyrenylphenyldihydroxysilane.

In addition, examples of the cyclic siloxane compound (1-2) include cyclic naphthylmethylsiloxane, cyclic naphthylphenylsiloxane, cyclic anthracenylmethylsiloxane, cyclic anthracenylphenylsiloxane, cyclic phenanthrylmethylsiloxane, and cyclic phenanthrylphenylsiloxane.

In addition, examples of the straight-chain organosiloxane (I-3) include naphthylmethylpolysiloxanes capped at both molecular terminals with silanol groups, naphthylphenylpolysiloxanes capped at both molecular terminals with silanol groups, anthracenylmethylpolysiloxanes capped at both molecular terminals with silanol groups, anthracenylphenylpolysiloxanes capped at both molecular terminals with silanol groups, phenanthrylmethylpolysiloxanes capped at both molecular terminals with silanol groups, and phenanthrylphenylpolysiloxanes capped at both molecular terminals with silanol groups.

Examples of the disiloxane (II-1) include 1,1,3,3-tetramethyldisiloxane, 1,3-diphenyl-1,3-dimethyldisiloxane, 1,3-dinaphthyl-1,3-dimethyldisiloxane, and 1,3-dianthracenyl-1,3-dimethyldisiloxane.

Examples of the silane compound (II-2) include alkoxysilanes such as dimethylmethoxysilane, methylphenylmethoxysilane, methylnaphthylmethoxysilane, anthracenylmethylmethoxysilane, dimethylethoxysilane, methylphenylethoxysilane, methylnaphthylethoxysilane, and anthracenylmethylethoxysilane; acetoxysilanes such as dimethylacetoxysilane, methylphenylacetoxysilane, methylnaphthylacetoxysilane, and anthracenylmethylacetoxysilane; chlorosilanes such as dimethylchlorosilane, methylphenylchlorosilane, methylnaphthylchlorosilane, and anthracenylmethylchlorosilane; and hydroxysilanes such as dimethylhydroxysilane, methylphenylhydroxysilane, methylnaphthylhydroxysilane, and anthracenylmethylhydroxysilane.

Examples of acids that can be used include hydrochloric acid, acetic acid, formic acid, nitric acid, oxalic acid, sulfuric acid, phosphoric acid, polyphosphoric acid, polyvalent carboxylic acid, trifluoromethane sulfonic acid, and ion exchange resins.

Examples of alkalis that can be used include hydroxides such as sodium hydroxide and potassium hydroxide; oxides such as magnesium oxide and calcium oxide; and hydrogen halide scavengers such as triethylamine, diethylamine, ammonia, picoline, pyridine, and 1,8-bis(dimethylamino)naphthalene.

In the preparation method described above, an organic solvent may be used. Examples of organic solvents that can be used include aromatic or aliphatic hydrocarbons and mixtures of two or more types thereof. Examples of preferable organic solvents include toluene and xylene.

Examples of this type of component (C) include organopolysiloxanes such as those mentioned below. In the formulas, Me, Ph, Naph, and Anth respectively represent a methyl group, a phenyl group, a naphthyl group, and an anthracenyl group, and n′ is an integer from 1 to 100.

HMe₂SiO(NaphMeSiO)_{n′}SiMe₂H

HMe₂SiO(NaphPhSiO)_{n′}SiMe₂H

HMePhSiO(NaphMeSiO)_{n′}SiMePhH

HMePhSiO(NaphPhSiO)_{n′}SiMePhH

HMe₂SiO(AnthMeSiO)_{n′}SiMe₂H

HMe₂SiO(AnthPhSiO)_{n′}SiMe₂H

HMePhSiO(AnthMeSiO)_{n′}SiMePhH

HMePhSiO(AnthPhSiO)_{n′}SiMePhH

The content of component (C) in the present composition, per 1 mol of total alkenyl groups in components (A) and (B), is in a range such that the silicon-bonded hydrogen atoms in component (C) is in a range of 0.1 to 5 mol, and preferably in a range of 0.5 to 2 mol. This is because when the content of component (C) is greater than or equal to the lower limit of the range described above, the composition is cured sufficiently, and when the content is less than or equal to the upper limit of the range described above, the heat resistance of the cured product improves, thus making it possible to improve the reliability of an optical semiconductor device produced using this composition.

Component (D) is a hydrosilylation reaction catalyst for accelerating the curing of this composition, and examples include platinum-based catalysts, rhodium-based catalysts, and palladium-based catalysts. Particularly, component (D) is preferably a platinum-based catalyst so that the curing of the present composition can be dramatically accelerated. Examples of the platinum-based catalyst include a platinum fine powder, chloroplatinic acid, an alcohol solution of chloroplatinic acid, a platinum-alkenylsiloxane complex, a platinum-olefin complex, and a platinum-carbonyl complex, with a platinum-alkenylsiloxane complex being preferred.

In this composition, the content of component (D) is not particularly limited as long as it is an amount that is effective for accelerating the curing of the composition, but the content is preferably an amount so that the catalyst metal in component (D) is in the range from 0.01 to 500 ppm, more preferably in the range from 0.01 to 100 ppm, and particularly preferably in the range from 0.01 to 50 ppm in mass units with respect to this composition. This is because when the content of component (D) is within the aforementioned range, the curing reaction of the resulting composition is accelerated.

This composition may also contain an adhesion-imparting agent in order to improve the adhesiveness of the resulting cured product. Preferred adhesion-imparting agents are organosilicon compounds having at least one alkoxy group bonded to a silicon atom in a molecule. This alkoxy group is exemplified by a methoxy group, an ethoxy group, a propoxy group, a butoxy group, and a methoxyethoxy group; and the methoxy group is particularly preferred. Moreover, non-alkoxy groups bonded to a silicon atom of this organosilicon compound are exemplified by substituted or non-substituted monovalent hydrocarbon groups such as alkyl groups, alkenyl groups, aryl groups, aralkyl groups, halogenated alkyl groups and the like; epoxy group-containing monovalent organic groups such as glycidoxyalkyl groups (such as a 3-glycidoxypropyl group, a 4-glycidoxybutyl group, and the like), epoxycyclohexylalkyl groups (such as a 2-(3,4-epoxycyclohexyl)ethyl group, a 3-(3,4-epoxycyclohexyl)propyl group, and the like) and oxiranylalkyl groups (such as a 4-oxiranylbutyl group, an 8-oxiranyloctyl group, and the like); acrylic group-containing monovalent organic groups such as a 3-methacryloxypropyl group and the like; and a hydrogen atom. This organosilicon compound preferably has a silicon-bonded alkenyl group or silicon-bonded hydrogen atom. Moreover, due to the ability to impart good adhesion with respect to various types of substrates, this organosilicon compound preferably has at least one epoxy group-containing monovalent organic group in a molecule. This type of organosilicon compound is exemplified by organosilane compounds, organosiloxane oligomers and alkyl silicates. Molecular structure of the organosiloxane oligomer or alkyl silicate is exemplified by a linear structure, partially branched linear structure, branched chain structure, cyclic structure, and reticulated structure. A linear chain structure, branched chain structure, and reticulated structure are particularly preferred. This type of organosilicon compound is exemplified by silane compounds such as 3-glycidoxypropyltrimethoxysilane, 2-(3,4-epoxycyclohexyl)ethyl trimethoxysilane, 3-methacryloxy propyltrimethoxysilane, and the like; siloxane compounds having at least one of silicon-bonded alkenyl groups and silicon-bonded hydrogen atoms, and at least one silicon-bonded alkoxy group in a molecule; mixtures of a silane compound or siloxane compound having at least one silicon-bonded alkoxy group and a siloxane compound having at least one silicon-bonded hydroxyl group and at least one silicon-bonded alkenyl group in a molecule; and methyl polysilicate, ethyl polysilicate, and epoxy group-containing ethyl polysilicate. The content of this adhesion-imparting agent is not particularly limited but is preferably in a range from 0.01 to 10 parts by mass with respect to a total of 100 parts by mass of components (A) to (D) described above so as to ensure that the adhesion of the resulting composition improves.

Moreover, this composition may also contain organohydrogenpolysiloxanes other than component (C) described above as additional optional components as long as the object of the present invention is not impaired. Examples of such organohydrogenpolysiloxanes include methylhydrogenpolysiloxnes capped at both molecular terminals with trimethylsiloxy groups, copolymers of dimethylsiloxanes and methylhydrogensiloxanes capped at both molecular terminals with trimethylsiloxy groups, copolymers of dimethylsiloxanes, methylhydrogensiloxanes, and methylphenylsiloxanes capped at both molecular terminals with trimethylsiloxy groups, dimethylpolysiloxanes capped at both molecular terminals with dimethylhydrogensiloxy groups, dimethylpolysiloxanes capped at both molecular terminals with methylphenylhydrogensiloxy groups, copolymers of dimethylsiloxanes and methylphenylsiloxanes capped at both molecular terminals with dimethylhydrogensiloxy groups, copolymers of dimethylsiloxanes and methylphenylsiloxanes capped at both molecular terminals with methylphenylhydrogensiloxy groups, methylphenylpolysiloxanes capped at both molecular terminals with dimethylhydrogensiloxy groups, methylphenylpolysiloxanes capped at both molecular terminals with methylphenylhydrogensiloxy groups, organopolysiloxane copolymers comprising a siloxane unit represented by the general formula: R′₃SiO_{1/2}, a siloxane unit represented by the general formula: R′₂HSiO_{1/2}, and a siloxane unit represented by the formula: SiO_{4/2}, organopolysiloxane copolymers comprising a siloxane unit represented by the general formula: R′₂HSiO_{1/2} and a siloxane unit represented by the formula: SiO_{4/2}, organopolysiloxane copolymers comprising a siloxane unit represented by the general formula: R′HSiO_{2/2}, a siloxane unit represented by the general formula: R′SiO_{3/2}, or a siloxane unit represented by the formula: HSiO_{3/2}, and mixtures of two or more such organopolysiloxanes. Moreover, R′ is an alkyl group having from 1 to 12 carbons, an aryl group having from 6 to 20 carbons, an aralkyl group having from 7 to 20 carbons, or a halogenated alkyl group having from 1 to 12 carbons. Examples of the alkyl group of R′ include methyl groups, ethyl groups, propyl groups, butyl groups, pentyl groups, hexyl groups, heptyl groups, octyl groups, nonyl groups, decyl groups, undecyl groups, and dodecyl groups. In addition, examples of the aryl group of R′ include phenyl groups, tolyl groups, xylyl groups, naphthyl groups, anthracenyl groups, phenanthryl groups, pyrenyl groups, and groups obtained by substituting hydrogen atoms in these aryl groups with alkyl groups such as methyl groups or ethyl groups; alkoxy groups such as methoxy groups or ethoxy groups; and halogen atoms such as chlorine atoms or bromine atoms. In addition, examples of the aralkyl group of R′ include benzyl groups, phenethyl groups, naphthyl ethyl groups, naphthyl propyl groups, anthracenyl ethyl groups, phenanthryl ethyl groups, pyrenyl ethyl groups, and groups obtained by substituting hydrogen atoms in these aralkyl groups with alkyl groups such as methyl groups or ethyl groups; alkoxy groups such as methoxy groups or ethoxy groups; and halogen atoms such as chlorine atoms or bromine atoms. In addition, examples of the halogenated alkyl group of include chloromethyl groups and 3,3,3-trifluoropropyl groups.

A reaction inhibitor, for example, an alkyne alcohol such as 2-methyl-3-butyn-2-ol, 3,5-dimethyl-1-hexyn-3-ol and 2-phenyl-3-butyn-2-ol; an ene-yne compound such as 3-methyl-3-penten-1-yne and 3,5-dimethyl-3-hexen-1-yne; or 1,3,5,7-tetramethyl-1,3,5,7-tetravinylcyclotetrasiloxane, 1,3,5,7-tetramethyl-1,3,5,7-tetrahexenylcyclotetrasiloxane or a benzotriazole may be incorporated as an optional component in the present composition. The content of the reaction inhibitor in this composition is not particularly limited but is preferably in the range of 0.0001 to 5 parts by mass with respect to a total of 100 parts by mass of components (A) to (D) described above.

This composition may also contain a fluorescent substance as an optional component. This fluorescent substance is exemplified by substances widely used in light emitting diodes (LEDs), such as yellow, red, green, and blue light-emitting fluorescent substances such as oxide fluorescent substances, oxynitride fluorescent substances, nitride fluorescent substances, sulfide fluorescent substances, oxysulfide fluorescent substances, and the like. Examples of oxide fluorescent substances include yttrium, aluminum, and garnet-type YAG green to yellow light-emitting fluorescent substances containing cerium ions; terbium, aluminum, and garnet-type TAG yellow light-emitting fluorescent substances containing cerium ions; and silicate green to yellow light-emitting fluorescent substances containing cerium or europium ions. Examples of oxynitride fluorescent substances include silicon, aluminum, oxygen, and nitrogen-type SiAlON red to green light-emitting fluorescent substances containing europium ions. Examples of nitride fluorescent substances include calcium, strontium, aluminum, silicon, and nitrogen-type CASN red light-emitting fluorescent substances containing europium ions. Examples of sulfide fluorescent substances include ZnS green light-emitting fluorescent substances containing copper ions or aluminum ions. Examples of oxysulfide fluorescent substances include Y₂O₂S red light-emitting fluorescent substances containing europium ions. These fluorescent substances may be used as one type or as a mixture of two or more types. The content of the fluorescent substance in this composition is not particularly limited but is preferably in the range of 0.1 to 70 mass % and more preferably in the range of 1 to 20 mass % in this composition.

Moreover, an inorganic filler such as silica, glass, alumina or zinc oxide; an organic resin fine powder of a polymethacrylate resin and the like; a heat-resistant agent, a dye, a pigment, a flame retardant, a solvent and the like may be incorporated as optional components in the present composition at levels that do not impair the objective of the present invention.

Of the components added as optional components, in order to sufficiently suppress the discoloration of the silver electrodes or the silver plating of the substrate in the optical semiconductor device due to sulfur-containing gas in the air, it is possible to add at least one type of a fine powder having an average particle size from 0.1 nm to 5 μm selected from a group comprising zinc oxide fine powders surface-coated with at least one type of oxide of an element selected from a group comprising Al, Ag, Cu, Fe, Sb, Si, Sn, Ti, Zr, and rare earth elements, zinc oxide fine powders surface-treated with organosilicon compounds not having alkenyl groups, and hydrate fine powders of zinc carbonate.

In a zinc oxide fine powder surface-coated with an oxide, examples of rare earth elements include yttrium, cerium, and europium. Examples of oxides on the surface of the zinc oxide powder include Al₂O₃, AgO, Ag₂O, Ag₂O₃, CuO, Cu₂O, FeO, Fe₂O₃, Fe₃O₄, Sb₂O₃, SiO₂, SnO₂, Ti₂O₃, TiO₂, Ti₃O₅, ZrO₂, Y₂O₃, CeO₂, Eu₂O₃, and mixtures of two or more types of these oxides.

In a zinc oxide fine powder surface-treated with an organosilicon compound, the organosilicon compound does not have alkenyl groups, and examples include organosilanes, organosilazanes, polymethylsiloxanes, organohydrogenpolysiloxanes, and organosiloxane oligomers. Specific examples include organochlorosilanes such as trimethylchlorosilane, dimethylchlorosilane, and methyltrichlorosilane; organotrialkoxysilanes such as methyltrimethoxysilane, methyltriethoxysilane, phenyltrimethoxysilane, ethyltrimethoxysilane, n-propyltrimethoxysilane, and γ-methacryloxypropyltrimethoxysilane; diorganodialkoxysilanes such as dimethyldimethoxysilane, dimethyldiethoxysilane, and diphenyldimethoxysilane; triorganoalkoxysilanes such as trimethylmethoxysilane and trimethylethoxysilane; partial condensates of these organoalkoxysilanes; organosilazanes such as hexamethyldisilazane; polymethylsiloxanes, organohydrogenpolysiloxanes, organosiloxane oligomers having a silanol group or an alkoxy group, and resin-like organopolysiloxanes consisting of an R¹⁰SiO_{3/2} unit (wherein R¹⁰ is a monovalent hydrocarbon group excluding alkenyl groups, examples of which include alkyl groups such as methyl groups, ethyl groups, or propyl groups; and aryl groups such as phenyl groups) or an SiO_{4/2} unit, and having a silanol group or an alkoxy group.

A hydrate fine powder of zinc carbonate is a compound in which water bonds to zinc carbonate, and a preferable compound is one in which the rate of weight decrease is at least 0.1 wt. % under heating conditions at 105° C. for 3 hours.

The content of the zinc oxide is an amount in a range from 1 ppm to 10% and preferably an amount in a range from 1 ppm to 5% of the composition in terms of mass units. This is because when the content of the component is greater than or equal to the lower limit of the range described above, the discoloration of the silver electrodes or the silver plating of the substrate in the optical semiconductor device due to a sulfur-containing gas is sufficiently suppressed, and when the content is less than or equal to the upper limit of the range described above, the fluidity of the resulting composition is not diminished.

In addition, the composition may also contain a triazole-based compound as an optional component to enable the further suppression of the discoloration of the silver electrodes or the silver plating of the substrate due to a sulfur-containing gas in the air. Examples of such components include 1H-1,2,3-triazole, 2H-1,2,3-triazole, 1H-1,2,4-triazole, 4H-1,2,4-triazole, 2-(2′-hydroxy-5′-methylphenyl)benzotriazole, 1H-1,2,3-triazole, 2H-1,2,3-triazole, 1H-1,2,4-triazole, 4H-1,2,4-triazole, benzotriazole, tolyltriazole, carboxybenzotriazole, 1H-benzotriazole-5-methylcarboxylate, 3-amino-1,2,4-triazole, 4-amino-1,2,4-triazole, 5-amino-1,2,4-triazole, 3-mercapto-1,2,4-triazole, chlorobenzotriazole, nitrobenzotriazole, aminobenzotriazole, cyclohexano[1,2-d]triazole, 4,5,6,7-tetrahydroxytolyltriazole, 1-hydroxybenzotriazole, ethylbenzotriazole, naphthotriazole, 1-N,N-bis(2-ethylhexyl)-[(1,2,4-triazole-1-yl)methyl]amine, 1-[N,N-bis(2-ethylhexyl)aminomethyl]benzotriazole, 1-[N,N-bis(2-ethylhexyl)aminomethyl]tolyltriazole, 1-[N,N-bis(2-ethylhexyl)aminomethyl]carboxybenzotriazole, 1-[N,N-bis(2-hydroxyethyl)-aminomethyl]benzotriazole, 1-[N,N-bis(2-hydroxyethyl)-aminomethyl]tolyltriazole, 1-[N,N-bis(2-hydroxyethyl)-aminomethyl]carboxybenzotriazole, 1-[N,N-bis(2-hydroxypropyl)aminomethyl]carboxybenzotriazole, 1-[N,N-bis(1-butyl)aminomethyl]carboxybenzotriazole, 1-[N,N-bis(1-octyl)aminomethyl]carboxybenzotriazole, 1-(2′,3′-di-hydroxypropyl)benzotriazole, 1-(2′,3′-di-carboxyethyl)benzotriazole, 2-(2′-hydroxy-3′,5′-di-tert-butylphenyl)benzotriazole, 2-(2′-hydroxy-3′,5′-amylphenyl)benzotriazole, 2-(2′-hydroxy-4′-octoxyphenyl)benzotriazole, 2-(2′-hydroxy-5′-tert-butylphenyl)benzotriazole, 1-hydroxybenzotriazole-6-carboxylic acid, 1-oleoylbenzotriazole, 5-amino-3-mercapto-1,2,4-triazole, 5-amino-1,2,4-triazole-3-carboxylic acid, 1,2,4-triazole-3-carboxyamide, 4-aminourazole, and 1,2,4-triazol-5-one. The content of this benzotriazole compound is not particularly limited but is an amount in a range from 0.01 ppm to 3% and preferably in a range from 0.1 ppm to 1% of the composition in terms of mass units.

The present composition is such that curing occurs either at room temperature or under heating, but it is preferable to heat the composition in order to achieve rapid curing. The heating temperature is preferably from 50 to 200° C.

The cured product of the present invention will now be described in detail.

The cured product of the present invention is formed by curing the aforementioned curable silicone composition. The shape of the cured product is not particularly limited, and examples include a sheet shape and a film shape. The cured product can be handled as a simple substance or may also be handled in a state in which the cured product covers or seals an optical semiconductor element or the like.

The optical semiconductor device of the present invention will now be explained in detail.

The optical semiconductor device of the present invention is produced by sealing an optical semiconductor element with a cured product of the curable silicone composition described above. Examples of such an optical semiconductor device of the present invention include a light emitting diode (LED), a photocoupler, and a CCD. Examples of optical semiconductor elements include light emitting diode (LED) chips and solid-state image sensing devices.

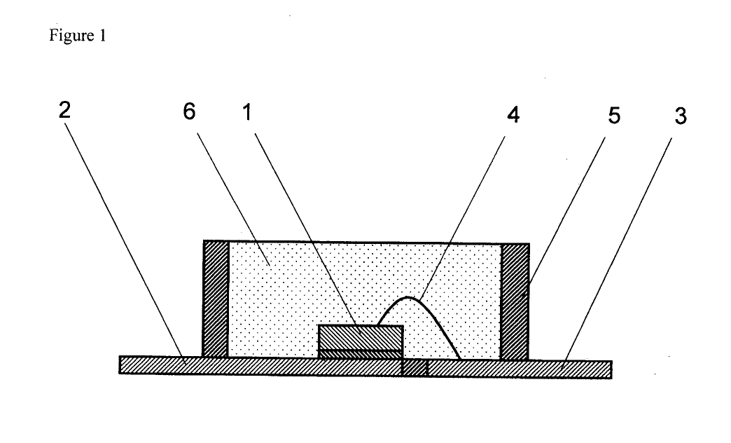

FIG. 1 illustrates a cross-sectional view of a single surface mounted type LED, which is one example of the optical semiconductor device of the present invention. In the LED illustrated in FIG. 1, an LED chip 1 is die-bonded to a lead frame 2, and the LED chip 1 and a lead frame 3 are wire-bonded by a bonding wire 4. A casing material 5 is provided around this LED chip 1, and the LED chip 1 inside the casing material 5 is sealed by a cured product 6 of the curable silicone composition of the present invention.

An example of a method of producing the surface mounted type LED illustrated in FIG. 1 is a method of die-bonding the LED chip 1 to the lead frame 2, wire-bonding the LED chip 1 and the lead frame 3 with a gold bonding wire 4, filling the inside of the casing material 5 provided around the LED chip 1 with the curable silicone composition of the present invention, and then curing the composition by heating at 50 to 200° C.

### EXAMPLES

The curable silicone composition, the cured product thereof, and the optical semiconductor device of the present invention will be described in detail hereinafter using Practical and Comparative Examples. The viscosity is the value at 25° C., and in Practical and Comparative Examples Me, Vi, Ph, and Naph respectively represent a methyl group, a vinyl group, a phenyl group, and a naphthyl group. The characteristics of the cured product of the curable silicone composition were measured as follows.

### [Refractive Index of the Cured Product]

A cured product is produced by heating the curable silicone composition at 150° C. for 2 hours in a circulating hot air oven. The refractive index of this cured product at 25° C. and a wavelength of 633 nm was measured using a refractometer.

### [Water Vapor Permeability of the Cured Product]

A cured film with a thickness of 1 mm was prepared by curing the curable silicone composition for 2 hours at 150° C. using a press. The water vapor permeability of the cured film was measured in accordance with the cup method of JIS Z0208 under conditions with a temperature of 40° C. and 90% relative humidity.

### Reference Example 1

First, 400 g (2.02 mol) of phenyltrimethoxysilane and 93.5 g (0.30 mol) of 1,3-divinyl-1,3-diphenyldimethyldisiloxane were loaded into a reaction vessel and mixed in advance. Next, 1.74 g (11.6 mmol) of trifluoromethane sulfonic acid was added, and 110 g (6.1 mol) of water was added and heat-refluxed for 2 hours while stirring. The mixture was then distilled at atmospheric pressure by heating until the mixture reached 85° C. Next, 89 g of toluene and 1.18 g (21.1 mmol) of potassium hydroxide were added, and after the mixture was distilled at atmospheric pressure by heating until the reaction temperature reached 120° C., the mixture was reacted for 6 hours at this temperature. The mixture was cooled to room temperature, and a neutralization reaction was performed by adding 0.68 g (11.4 mmol) of acetic acid. The produced salt was filtered, and low boiling point substances were removed from the obtained transparent solution by heating under reduced pressure, thereby producing 347 g (yield: 98%) of an organopolysiloxane resin represented by the average unit formula:

(MePhViSiO_{1/2})_{0.23}(PhSiO_{3/2})_{0.77}

### Reference Example 2

First, 148.8 g (0.6 mol) of 1-naphthyltrimethoxysilane and 37.2 g (0.2 mol) of 1,3-divinyltetramethyl disiloxane were loaded into a reaction vessel and mixed in advance. Next, 0.136 g (0.9 mmol) of trifluoromethane sulfonic acid was added, and 35.6 g (1.98 mol) of water was added and heat-refluxed for 2 hours while stirring. The mixture was then distilled at atmospheric pressure by heating until the mixture reached 85° C. Next, 62.0 g of toluene and 0.194 g (3.5 mmol) potassium hydroxide were added, and after the mixture was distilled at atmospheric pressure by heating until the reaction temperature reached 120° C., the mixture was reacted for 6 hours at this temperature. The mixture was then cooled to room temperature, and a neutralization reaction was performed by adding 0.21 g (3.5 mmol) of acetic acid. After the salt that was produced was filtered out, the low-boiling-point substances were distilled out of the resulting clear liquid by heating under reduced pressure, thereby producing 130.0 g (yield: 89.9%) of a clear, colorless rubber-like viscous liquid. As a result of NMR analysis, it was found that this liquid is an organopolysiloxane resin represented by the average unit formula:

(Me₂ViSiO_{1/2})_{0.40}(NaphSiO_{3/2})_{0.60}

The mass average molecular weight (Mw) of this organopolysiloxane resin was 1,000, the dispersity (Mw/Mn) was 1.03, and the refractive index was 1.603.

### Reference Example 3

First, 892.8 g (3.6 mol) of 1-naphthyltrimethoxysilane and 372.0 g (1.2 mol) of 1,3-divinyl-1,3-diphenyldimethyldisiloxane were loaded into a reaction vessel and mixed in advance. Next, 6.15 g (41 mmol) of trifluoromethane sulfonic acid was added, and 213.84 g (11.88 mol) of water was added and heat-refluxed for 2 hours while stirring. The mixture was then distilled at atmospheric pressure by heating until the mixture reached 85° C. Next, 435.6 g of toluene and 3.28 g (58.6 mmol) of potassium hydroxide were added, and after the mixture was distilled at atmospheric pressure by heating until the reaction temperature reached 120° C., the mixture was reacted for 6 hours at this temperature. The mixture was then cooled to room temperature, and a neutralization reaction was performed by adding 3.524 g (58.7 mmol) of acetic acid. The produced salt was filtered, and low boiling point substances were removed from the obtained transparent solution by heating under reduced pressure, thereby producing 957.4 g (yield: 94.2%) of an organopolysiloxane resin represented by the average unit formula:

(MePhViSiO_{1/2})_{0.40}(NaphSiO_{3/2})_{0.60}

### Reference Example 4

52.0 g (0.39 mol) of 1,1,3,3-tetramethyldisiloxane, 31.1 g (0.52 mol) of acetic acid, and 0.15 g (0.98 mmol) of trifluoromethane sulfonic acid were placed in a reaction vessel, and after the mixture was stirred while heating, 60.0 g (0.26 mol) of naphthylmethyldimethoxysilane was added dropwise into the mixture at 45 to 50° C. After completion of drop-wise addition, the mixture was heated and stirred for 30 minutes at 50° C. Next, 26.4 g (0.26 mol) of acetic anhydride was added dropwise to the mixture, and after the completion of dropwise addition, the mixture was stirred while heating for 30 minutes at 50° C. The mixture was then cooled, and after toluene and water were added and stirred, the mixture was left to stand. The water layer of the lower layer was extracted, and the toluene layer of the upper layer was repeatedly washed with water. After the water layer was extracted, the low-boiling-point substances were distilled out of the toluene layer by heating under reduced pressure, thereby producing 75.2 g (yield: 90.1%) of a clear liquid. It was found that this liquid is an organotrisiloxane having a refractive index of 1.515 and a viscosity of 8.3 mPa·s and being represented by the formula:

HMe₂SiOMeNaphSiOSiMe₂H

### Reference Example 5

50.0 g (0.22 mol) of naphthylmethyldimethoxysilane and 0.101 g (0.67 mmol) of trifluoromethane sulfonic acid were placed in a reaction vessel, and after the mixture was stirred while heating, 7.77 g (0.13 mol) of acetic acid was added dropwise into the mixture at 45 to 50° C. After completion of drop-wise addition, the mixture was heated and stirred for 30 minutes at 50° C. The low-boiling-point substances were then distilled out by heating under reduced pressure. After the mixture was cooled, 17.3 g (0.13 mol) of 1,1,3,3-tetramethyldisiloxane was added dropwise to the mixture, and the mixture was heated until the reaction temperature reached 45° C. Next, 10.4 g (0.17 mol) of acetic acid was added dropwise to the mixture at 45 to 50° C. After completion of dropwise addition, the mixture was heated and stirred for 60 minutes at 50° C. The mixture was air-cooled or water-cooled, and 8.82 g (0.086 mol) of acetic anhydride was added dropwise to the mixture while the system was maintained at a temperature of 60° C. or less. After completion of dropwise addition, the mixture was heated and stirred for 60 minutes at 50° C. Next, toluene and water were added, and after the mixture was stirred, the mixture was left to stand. The water layer of the lower layer was extracted, and the toluene layer of the upper layer was repeatedly washed with water. After the water layer was extracted, the low-boiling-point substances were distilled out of the toluene layer by heating under reduced pressure, thereby producing 45.4 g (yield: 87.9%) of a clear liquid. It was found that this liquid is an organopolysiloxane having a refractive index of 1.552 and a viscosity of 118.3 mPa·s and being represented by the average formula:

HMe₂SiO(MeNaphSiO)_{2.5}SiMe₂H

### Reference Example 6

20.1 g (0.15 mol) of 1,1,3,3-tetramethyldisiloxane, 12.1 g (0.20 mol) of acetic acid, and 0.06 g (0.40 mmol) of trifluoromethane sulfonic acid were placed in a reaction vessel, and after the mixture was stirred while heating, 29.4 g (0.100 mol) of naphthylphenyldimethoxysilane and 29.4 g of toluene were added dropwise into the mixture at 45 to 50° C. After completion of drop-wise addition, the mixture was heated and stirred for 30 minutes at 50° C. The mixture was air-cooled or water-cooled, and 10.2 g (0.100 mol) of acetic anhydride was added dropwise to the mixture while the system was maintained at a temperature of 60° C. or less. After completion of dropwise addition, the mixture was heated and stirred for 30 minutes at 50° C. Next, toluene and water were added, and after the mixture was stirred, the mixture was left to stand. The water layer of the lower layer was extracted, and the toluene layer of the upper layer was repeatedly washed with water. After the water layer of the lower layer was extracted, the low-boiling-point substances were distilled out of the toluene layer by heating under reduced pressure, thereby producing 35.52 g (yield: 93.0%) of a clear liquid. It was found that this liquid is an organotrisiloxane having a refractive index of 1.544 and a viscosity of 29.2 mPa·s and being represented by the formula:

HMe₂SiOPhNaphSiOSiMe₂H

### Reference Example 7

11.0 g (0.043 mol) of 1,3-dimethyl-1,3-diphenyldisiloxane, 4.80 g (0.08 mol) of acetic acid, and 0.111 g (0.74 mmol) of trifluoromethane sulfonic acid were placed in a reaction vessel, and after the mixture was stirred while heating, 9.28 g (0.04 mol) of naphthylmethyldimethoxysilane was added dropwise to the mixture while heating to 45 to 50° C. After completion of dropwise addition, the mixture was heated and stirred for 60 minutes at 50° C. The mixture was air-cooled or water-cooled, and 4.084 g (0.04 mol) of acetic anhydride was added dropwise to the mixture while the system was maintained at a temperature of 60° C. or less. After completion of dropwise addition, the mixture was heated and stirred for 60 minutes at 50° C. Next, toluene and water were added, and after the mixture was stirred, the mixture was left to stand. The water layer of the lower layer was extracted, and the toluene layer of the upper layer was repeatedly washed with water. After the water layer of the lower layer was extracted, the low-boiling-point substances were distilled out of the toluene layer by heating under reduced pressure, thereby producing 14.7 g (yield: 82.5%) of a clear liquid. It was found that this liquid is an organotrisiloxane having a refractive index of 1.555 and a viscosity of 19.8 mPa·s and being represented by the formula:

HMePhSiOMeNaphSiOSiMePhH

### Practical Example 1

70.5 parts by mass of the organopolysiloxane resin prepared in Reference Example 2, 29.5 parts by mass of the organotrisiloxane prepared in Reference Example 4 (an amount at which the quantity of silicon-bonded hydrogen atoms in the component is 1 mole with respect to 1 mole of the vinyl groups in the organopolysiloxane resin), and 0.25 parts by mass of a solution of a platinum-1,3-divinyl-1,1,3,3-tetramethyldisiloxane complex in 1,3,5,7-tetramethyl-1,3,5,7-tetravinylcyclotetrasiloxane (the solution containing 0.1 mass % of platinum) were mixed, thereby producing a curable silicone composition having a viscosity of 27.5 Pa·s. The refractive index and water vapor permeability of a cured product of this curable silicone composition were evaluated. The results are shown in Table 1.

### Practical Example 2

71.5 parts by mass of the organopolysiloxane resin prepared in Reference Example 3, 28.5 parts by mass of the organotrisiloxane prepared in Reference Example 4 (an amount at which the quantity of silicon-bonded hydrogen atoms in the component is 1 mole with respect to 1 mole of the vinyl groups in the organopolysiloxane resin), and 0.25 parts by mass of a solution of a platinum-1,3-divinyl-1,1,3,3-tetramethyldisiloxane complex in 1,3,5,7-tetramethyl-1,3,5,7-tetravinylcyclotetrasiloxane (the solution containing 0.1 mass % of platinum) were mixed, thereby producing a curable silicone composition having a viscosity of 7.72 Pa·s. The refractive index and water vapor permeability of a cured product of this curable silicone composition were evaluated. The results are shown in Table 1.

### Comparative Example 1

68.5 parts by mass of the organopolysiloxane resin prepared in Reference Example 2, 31.5 parts by mass of an organopolysiloxane represented by the formula:

HMe₂SiOPh₂SiOSiMe₂H

(an amount at which the quantity of silicon-bonded hydrogen atoms in the component is 1 mole with respect to 1 mole of the vinyl groups in the organopolysiloxane resin), and 0.25 parts by mass of a solution of a platinum-1,3-divinyl-1,1,3,3-tetramethyldisiloxane complex in 1,3,5,7-tetramethyl-1,3,5,7-tetravinylcyclotetrasiloxane (the solution containing 0.1 mass % of platinum) were mixed, thereby producing a curable silicone composition having a viscosity of 9.3 Pa·s. The refractive index and water vapor permeability of a cured product of this curable silicone composition were evaluated. The results are shown in Table 1.

TABLE 1

| | Category | | |
|---|---|---|---|
| | | | Comparative |
| | Present Invention | | Example |
| | Practical | Practical | Comparative |
| Item | Example 1 | Example 2 | Example 1 |
| Refractive index | 1.592 | 1.603 | 1.589 |
| Water vapor permeability | 2.4 | 2.2 | 2.9 |
| (g/m² · 24 h) | | | |

### Practical Example 3

74.0 parts by mass of an organopolysiloxane resin represented by the average unit formula:

(Me₂ViSiO_{1/2})_{0.25}(PhSiO_{3/2})_{0.75},

26.0 parts by mass of the organotrisiloxane prepared in Reference Example 4 (an amount at which the quantity of silicon-bonded hydrogen atoms in the component is 1 mole with respect to 1 mole of the vinyl groups in the organopolysiloxane resin), and 0.25 parts by mass of a solution of a platinum-1,3-divinyl-1,1,3,3-tetramethyldisiloxane complex in 1,3,5,7-tetramethyl-1,3,5,7-tetravinylcyclotetrasiloxane (the solution containing 0.1 mass % of platinum) were mixed, thereby producing a curable silicone composition having a viscosity of 3.44 Pa·s. The refractive index and water vapor permeability of a cured product of this curable silicone composition were evaluated. The results are shown in Table 2.

### Practical Example 4

77.5 parts by mass of the organopolysiloxane resin prepared in Reference Example 1, 22.5 parts by mass of the organotrisiloxane prepared in Reference Example 4 (an amount at which the quantity of silicon-bonded hydrogen atoms in the component is 1 mole with respect to 1 mole of the vinyl groups in the organopolysiloxane resin), and 0.25 parts by mass of a solution of a platinum-1,3-divinyl-1,1,3,3-tetramethyldisiloxane complex in 1,3,5,7-tetramethyl-1,3,5,7-tetravinylcyclotetrasiloxane (the solution containing 0.1 mass % of platinum) were mixed, thereby producing a curable silicone composition having a viscosity of 7.23 Pa·s. The refractive index and water vapor permeability of a cured product of this curable silicone composition were evaluated. The results are shown in Table 2.

### Practical Example 5

72.0 parts by mass of an organopolysiloxane resin represented by the average unit formula:

(Me₂ViSiO_{1/2})_{0.25}(PhSiO_{3/2})_{0.75},

28.0 parts by mass of the organotrisiloxane prepared in Reference Example 6 (an amount at which the quantity of silicon-bonded hydrogen atoms in the component is 1 mole with respect to 1 mole of the vinyl groups in the organopolysiloxane resin), and 0.25 parts by mass of a solution of a platinum-1,3-divinyl-1,1,3,3-tetramethyldisiloxane complex in 1,3,5,7-tetramethyl-1,3,5,7-tetravinylcyclotetrasiloxane (the solution containing 0.1 mass % of platinum) were mixed, thereby producing a curable silicone composition having a viscosity of 12.5 Pa·s. The refractive index and water vapor permeability of a cured product of this curable silicone composition were evaluated. The results are shown in Table 2.

### Practical Example 6

67.5 parts by mass of an organopolysiloxane resin represented by the average unit formula:

(Me₂ViSiO_{1/2})_{0.25}(PhSiO_{3/2})_{0.75},

32.5 parts by mass of the organotrisiloxane prepared in Reference Example 7 (an amount at which the quantity of silicon-bonded hydrogen atoms in the component is 1 mole with respect to 1 mole of the vinyl groups in the organopolysiloxane resin), and 0.25 parts by mass of a solution of a platinum-1,3-divinyl-1,1,3,3-tetramethyldisiloxane complex in 1,3,5,7-tetramethyl-1,3,5,7-tetravinylcyclotetrasiloxane (the solution containing 0.1 mass % of platinum) were mixed, thereby producing a curable silicone composition having a viscosity of 2.10 Pa·s. The refractive index and water vapor permeability of a cured product of this curable silicone composition were evaluated. The results are shown in Table 2.

### Comparative Example 2

73.4 parts by mass of an organopolysiloxane resin represented by the average unit formula:

(Me₂ViSiO_{1/2})_{0.25}(PhSiO_{3/2})_{0.75},

26.6 parts by mass of an organotrisiloxane represented by the formula:

HMe₂SiOPh₂SiOSiMe₂H

(an amount at which the quantity of silicon-bonded hydrogen atoms in the component is 1 mole with respect to 1 mole of the vinyl groups in the organopolysiloxane resin), and 0.25 parts by mass of a solution of a platinum-1,3-divinyl-1,1,3,3-tetramethyldisiloxane complex in 1,3,5,7-tetramethyl-1,3,5,7-tetravinylcyclotetrasiloxane (the solution containing 0.1 mass % of platinum) were mixed, thereby producing a curable silicone composition having a viscosity of 2.30 Pa·s. The refractive index and water vapor permeability of a cured product of this curable silicone composition were evaluated. The results are shown in Table 2.

### Comparative Example 3

76.6 parts by mass of the organopolysiloxane resin prepared in Reference Example 1, 23.4 parts by mass of an organopolysiloxane represented by the formula:

HMe₂SiOPh₂SiOSiMe₂H

(an amount at which the quantity of silicon-bonded hydrogen atoms in the component is 1 mole with respect to 1 mole of the vinyl groups in the organopolysiloxane resin), and 0.25 parts by mass of a solution of a platinum-1,3-divinyl-1,1,3,3-tetramethyldisiloxane complex in 1,3,5,7-tetramethyl-1,3,5,7-tetravinylcyclotetrasiloxane (the solution containing 0.1 mass % of platinum) were mixed, thereby producing a curable silicone composition having a viscosity of 4.60 Pa·s. The refractive index and water vapor permeability of a cured product of this curable silicone composition were evaluated. The results are shown in Table 2.

TABLE 2

| | Category | | | | | |
|---|---|---|---|---|---|---|
| | Present Invention | | | | | |
| | Practical | Practical | Practical | Practical | Comparative Examples | |
| | Example | Example | Example | Example | Comparative | Comparative |
| Item | 3 | 4 | 5 | 6 | Example 2 | Example 3 |
| Refractive | 1.551 | 1.567 | 1.559 | 1.563 | 1.540 | 1.564 |
| index | | | | | | |
| Water vapor | 7.11 | 4.86 | 6.47 | 6.78 | 11.4 | 6.7 |
| permeability | | | | | | |
| (g/m² · 24 h) | | | | | | |

### Practical Example 7

53.0 parts by mass of an organopolysiloxane resin represented by the average unit formula:

(Me₂ViSiO_{1/2})_{0.25}(PhSiO_{3/2})_{0.75},

15.0 parts by mass of a methylphenylpolysiloxane having a viscosity of 3,000 mPa·s and being capped at both molecular terminals with dimethylvinylsiloxy groups, 27.0 parts by mass of the organopolysiloxane prepared in Reference Example 5, 5.0 parts by mass of an organopolysiloxane represented by the average unit formula:

(HMe₂SiO_{1/2})_{0.60}(PhSiO_{3/2})_{0.40}

(an amount at which the total quantity of silicon-bonded hydrogen atoms in the organopolysiloxane prepared in Reference Example 5 and in this component is 1 mole with respect to a total of 1 mole of the vinyl groups in the organopolysiloxane resin and the methylphenylpolysiloxane), and 0.25 parts by mass of a solution of a platinum-1,3-divinyl-1,1,3,3-tetramethyldisiloxane complex in 1,3,5,7-tetramethyl-1,3,5,7-tetravinylcyclotetrasiloxane (the solution containing 0.1 mass % of platinum) were mixed, thereby producing a curable silicone composition having a viscosity of 6.06 Pa·s. The refractive index and water vapor permeability of a cured product of this curable silicone composition were evaluated. The results are shown in Table 3.

### Practical Example 8

50.0 parts by mass of the organopolysiloxane resin prepared in Reference Example 2, 15.0 parts by mass of a methylphenylpolysiloxane having a viscosity of 3,000 mPa·s and being capped at both molecular terminals with dimethylvinylsiloxy groups, 30.0 parts by mass of the organopolysiloxane prepared in Reference Example 5, 5.0 parts by mass of an organopolysiloxane represented by the average unit formula:

(HMe₂SiO_{1/2})_{0.60}(PhSiO_{3/2})_{0.40}

(an amount at which the total quantity of silicon-bonded hydrogen atoms in the organopolysiloxane prepared in Reference Example 5 and in this component is 1 mole with respect to a total of 1 mole of the vinyl groups in the organopolysiloxane resin and the methylphenylpolysiloxane), and 0.25 parts by mass of a solution of a platinum-1,3-divinyl-1,1,3,3-tetramethyldisiloxane complex in 1,3,5,7-tetramethyl-1,3,5,7-tetravinylcyclotetrasiloxane (the solution containing 0.1 mass % of platinum) were mixed, thereby producing a curable silicone composition having a viscosity of 28.0 Pa·s. The refractive index and water vapor permeability of a cured product of this curable silicone composition were evaluated. The results are shown in Table 3.

### Practical Example 9

26.0 parts by mass of an organopolysiloxane resin represented by the average unit formula:

(Me₂ViSiO_{1/2})_{0.25}(PhSiO_{3/2})_{0.75},

25.0 parts by mass of the organopolysiloxane resin prepared in Reference Example 2, 15.0 parts by mass of a methylphenylpolysiloxane having a viscosity of 3,000 mPa·s and being capped at both molecular terminals with dimethylvinylsiloxy groups, 29.0 parts by mass of the organopolysiloxane prepared in Reference Example 5, 5.0 parts by mass of an organopolysiloxane represented by the average unit formula:

(HMe₂SiO_{1/2})_{0.60}(PhSiO_{3/2})_{0.40}

(an amount at which the quantity of silicon-bonded hydrogen atoms in the organopolysiloxane prepared in Reference Example 5 and in this component is 1 mole with respect to a total of 1 mole of the vinyl groups in the two types of organopolysiloxane resins and the methylphenylpolysiloxane), and 0.25 parts by mass of a solution of a platinum-1,3-divinyl-1,1,3,3-tetramethyldisiloxane complex in 1,3,5,7-tetramethyl-1,3,5,7-tetravinylcyclotetrasiloxane (the solution containing 0.1 mass % of platinum) were mixed, thereby producing a curable silicone composition having a viscosity of 12.1 Pa·s. The refractive index and water vapor permeability of a cured product of this curable silicone composition were evaluated. The results are shown in Table 3.

### Comparative Example 4

52.0 parts by mass of an organopolysiloxane resin represented by the average unit formula:

(Me₂ViSiO_{1/2})_{0.25}(PhSiO_{3/2})_{0.75},

15.0 parts by mass of a methylphenylpolysiloxane having a viscosity of 3,000 mPa·s and being capped at both molecular terminals with dimethylvinylsiloxy groups, 28.0 parts by mass of an organopolysiloxane represented by the average formula:

HMe₂SiO(Ph₂SiO)_{2.5}SiMe₂H,

5.0 parts by mass of an organopolysiloxane represented by the average unit formula:

(HMe₂SiO_{1/2})_{0.60}(PhSiO_{3/2})_{0.40}

(an amount at which the total quantity of silicon-bonded hydrogen atoms in the organopolysiloxane represented by the aforementioned average formula and in this component is 1 mole with respect to a total of 1 mole of the vinyl groups in the organopolysiloxane resin and the methylphenylpolysiloxane), and 0.25 parts by mass of a solution of a platinum-1,3-divinyl-1,1,3,3-tetramethyldisiloxane complex in 1,3,5,7-tetramethyl-1,3,5,7-tetravinylcyclotetrasiloxane (the solution containing 0.1 mass % of platinum) were mixed, thereby producing a curable silicone composition having a viscosity of 10.6 Pa·s. The refractive index and water vapor permeability of a cured product of this curable silicone composition were evaluated. The results are shown in Table 3.

### Comparative Example 5

47.0 parts by mass of the organopolysiloxane resin prepared in Reference Example 2, 15.0 parts by mass of a methylphenylpolysiloxane having a viscosity of 3,000 mPa·s and being capped at both molecular terminals with dimethylvinylsiloxy groups, 33.0 parts by mass of an organopolysiloxane represented by the average formula:

HMe₂SiO(Ph₂SiO)_{2.5}SiMe₂H,

5.0 parts by mass of an organopolysiloxane represented by the average unit formula:

(HMe₂SiO_{1/2})_{0.60}(PhSiO_{3/2})_{0.40}

(an amount at which the total quantity of silicon-bonded hydrogen atoms in the organopolysiloxane represented by the aforementioned average formula and in this component is 1 mole with respect to a total of 1 mole of the vinyl groups in the organopolysiloxane resin and the methylphenylpolysiloxane), and 0.25 parts by mass of a solution of a platinum-1,3-divinyl-1,1,3,3-tetramethyldisiloxane complex in 1,3,5,7-tetramethyl-1,3,5,7-tetravinylcyclotetrasiloxane (the solution containing 0.1 mass % of platinum) were mixed, thereby producing a curable silicone composition having a viscosity of 16.5 Pa·s. The refractive index and water vapor permeability of a cured product of this curable silicone composition were evaluated. The results are shown in Table 3.

TABLE 3

| | Category | | | | |
|---|---|---|---|---|---|
| | | | | Comparative Examples | |
| | Present Invention | | | Com- | Com- |
| | Practical | Practical | Practical | parative | parative |
| Item | Example 7 | Example 8 | Example 9 | Example 4 | Example 5 |
| Refractive | 1.553 | 1.583 | 1.567 | 1.553 | 1.581 |
| index | | | | | |
| Water vapor | 9.09 | 2.86 | 4.70 | 10.59 | 4.749 |
| permeability | | | | | |
| (g/m² · 24 h) | | | | | |

### INDUSTRIAL APPLICABILITY

The curable silicone composition of the present invention has excellent handling and processability and can form a curable product which undergoes minimal yellowing due to thermal aging and sufficiently suppresses the discoloration of silver electrodes or the silver plating of a substrate due to a sulfur-containing gas in the air. Therefore, the curable silicone composition is suitable as a sealant, a coating agent, or an adhesive for an optical semiconductor element of an optical semiconductor device or a protective agent for the silver electrodes or the silver plating of a substrate of a liquid crystal terminal part.

### DESCRIPTION OF SYMBOLS

1 Optical semiconductor element
2 Lead frame
3 Lead frame
4 Bonding wire
5 Casing material
6 Cured product of the curable silicone composition

1. A curable silicon composition comprising:
(A) an organopolysiloxane resin having at least two alkenyl groups in a molecule and represented by the average unit formula:
(R¹R²₂SiO_{1/2})ₐ(R³₂SiO_{2/2})_{b}(R⁴SiO_{3/2})_{c}
wherein R¹ is an alkenyl group having from 2 to 12 carbons; R² are the same or different, and are each an alkyl group having from 1 to 12 carbons, an alkenyl group having from 2 to 12 carbons, an aryl group having from 6 to 20 carbons, or an aralkyl group having from 7 to 20 carbons; R³ are the same or different, and are each an alkyl group having from 1 to 12 carbons, an alkenyl group having from 2 to 12 carbons, or a phenyl group; R⁴ is an aryl group having from 6 to 20 carbons, or an aralkyl group having from 7 to 20 carbons; and a, b, and c are numbers that satisfy such that 0.01≦a≦0.5, 0≦b≦0.7, 0.1≦c<0.9, and a+b+c=1;
(B) a straight-chain organopolysiloxane having at least two alkenyl groups and not having silicon-bonded hydrogen atoms in a molecule, in an amount of 0 to 70 mass % of the composition;
(C) an organopolysiloxane represented by the general formula: 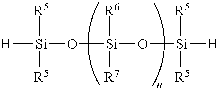
wherein R⁵ are the same or different, and are each an alkyl group having from 1 to 12 carbons, an aryl group having from 6 to 20 carbons, or an aralkyl group having from 7 to 20 carbons; R⁶ is a condensed polycyclic aromatic group or a group including a condensed polycyclic aromatic group; R⁷ is an alkyl group having from 1 to 12 carbons or a phenyl group; and n is an integer from 1 to 100, in an amount such that the number of silicon-bonded hydrogen atoms in the present component is from 0.1 to 5 moles per 1 mol of total alkenyl groups in components (A) and (B); and
(D) an effective amount of a hydrosilylation reaction catalyst.

2. The curable silicone composition according to claim 1, wherein R⁴ in component (A) is a phenyl group or a naphthyl group.

3. The curable silicone composition according to claim 1, wherein R⁶ in component (C) is a naphthyl group.

4. A cured product produced by curing the curable silicone composition according to claim 1.

5. An optical semiconductor device comprising an optical semiconductor element sealed by a cured product of the curable silicone composition according to claim 1.

6. The curable silicone composition according to claim 2, wherein R⁶ in component (C) is a naphthyl group.

7. A cured product produced by curing the curable silicone composition according to claim 2.

8. A cured product produced by curing the curable silicone composition according to claim 3.

9. An optical semiconductor device comprising an optical semiconductor element sealed by a cured product of the curable silicone composition according to claim 2.

10. An optical semiconductor device comprising an optical semiconductor element sealed by a cured product of the curable silicone composition according to claim 3.
